(19) United States
(12) Patent Application Publication
(10) Pub. No.: US 2002/0024982 A1
(43) Pub. Date: Feb. 28, 2002

(54) Semiconductor laser device

(76) Inventor: Akira Iketani, Tokyo (JP)

Correspondence Address: COUDERT BROTHERS, Suite 3300, 4 Embarcadero Center, San Francisco, CA, 94111, US

(21) Appl. No.: 09/886,141

(22) Filed: Jun. 20, 2001

(30) Foreign Application Priority Data
Aug. 22, 2000 (JP) 2000-251007

(51) Int. Cl. H01S 5/00

(52) U.S. Cl. 372/45

(57) ABSTRACT

The semiconductor laser device includes the semiconductor substrate made of GaAs, the lower clad layer above the substrate, the well layer made of InGaAs above the lower clad layer, and the upper clad layer above the well layer. Furthermore, the diffusion preventing layer is formed on at least one surface of the substrate, lower clad layer, well layer, and upper clad layer. This diffusion preventing layer is characterized in that it has a forbidden band wider than that of the well layer. Finally, the optical damage suppressing layer is formed above the diffusion preventing layer. This optical damage suppressing layer also has a forbidden band wider than that of the well layer.

### FIELD OF THE INVENTION

The present invention relates to a semiconductor laser device having an active layer of at least one quantum well structure. More particularly, this invention relates to a semiconductor laser device having higher reliability.

### BACKGROUND OF THE INVENTION

GaAs-based semiconductor laser elements are widely used in excitation light sources of optical amplifiers and the like. When the GaAs-based semiconductor laser element is used in excitation light sources, it is necessary that its light output is high. However, when the light output of the semiconductor laser element is increased, following phenomenon disadvantageously occur at the laser end facet of the semiconductor laser element. Firstly there occurs an optical damage, secondly there occurs a corrosion of the laser end facet when the laser element is operated over a long period. It is believed that these phenomenon are caused because of increase of the temperature of the end facet (resonator surface), contraction of the band gap, photo-absorption, recombination current, and a combination of one or more of these.

When the light output of the semiconductor laser element is increased, the optical damage and end facet corrosion become more conspicuous because the light density at the end facet increases. Sometimes the deterioration is so high that the generation of laser is suddenly stopped. In order to overcome these problems, it is desirable to have a semiconductor laser element in which light intensity is reduced only near the end facet.

### SUMMARY OF THE INVENTION

It is an object of the present invention to provide an improved semiconductor laser device.

The semiconductor laser device according to one aspect of the present invention comprises a diffusion preventing layer larger having a forbidden band that is wider than that of the well layer is provided between the well layer and the optical damage suppressing layer.

The semiconductor laser device according to one aspect of the present invention comprises an optical damage suppressing layer having a composition of In_{0.08-0.12}Ga_{0.88-0.92}As_{0.76-0.84}P_{0.16-0.24}.

Other objects and features of this invention will become apparent from the following description with reference to the accompanying drawings.

### BRIEF DESCRIPTION OF THE DRAWINGS

FIG. 1 shows a cross section of a laminated structure of an example of a conventional semiconductor laser device;

FIG. 2 shows a fabrication process of the conventional semiconductor laser;

FIG. 3 is a continuation of the fabrication process of the conventional semiconductor laser;

Upper portion of FIG. 4 shows a cross section of a laminated structure of the conventional semiconductor laser device, and the lower portion shows distributions of In and Ga content in this semiconductor laser device;

Upper portion of FIG. 5 shows a cross section of a laminated structure of a semiconductor laser device according to a first embodiment of the present invention, and the lower portion shows distributions of In and Ga content in this semiconductor laser device; and

Upper portion of FIG. 6 shows a cross section of a laminated structure of a semiconductor laser device according to a second embodiment of the present invention, and the lower portion shows distributions of In and Ga content in this semiconductor laser device.

### DESCRIPTION OF THE PREFERRED EMBODIMENTS

Preferred embodiments of the present invention will be explained below with reference to the accompanying drawings.

As a countermeasure to the above desire to have a semiconductor laser element in which light intensity is reduced only near the end facet, Japanese Patent Application Laid-Open No. 8-32167 discloses a semiconductor laser device having a GaAs substrate a strain quantum well layer comprised of an InGaAs layer and formed as an active layer and an oscillator comprised of a pair of parallel cleavage surfaces. Furthermore, InGaP layer is formed on the resonator surface to suppress the optical damage.

FIG. 1 to FIG. 3 explain the fabrication process of the conventional semiconductor laser device.

The substrate 2 is made of n-type GaAs. Following layers are successively formed on this substrate 2 using MOCVD method. That is, the lower clad layer 3 made of n-type Al_{0.3}Ga_{0.7}As layer, and having a thickness of approximately 2 μm, the active layer 4 having a strain quantum well layer of In_{0.1}Ga_{0.9}As layer, the upper clad layer 5 made of p-type Al_{0.3}Ga_{0.7}As and having a thickness of approximately 2 μm, and the contact layer 8 made of p-type GaAs.

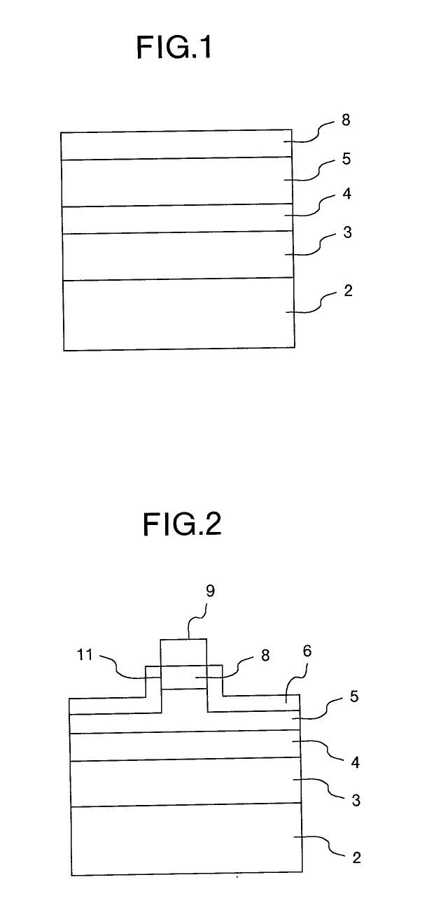

Thereafter, as shown in FIG. 2, a resist film 9 having a width of approximately 3 μm is formed in correspondence to a stripe formed perpendicular to a surface to be cleaved. Furthermore, upper parts of the contact layer 8 and the upper clad layer 5 that are not covered by the resist film 9 are removed by etching. Thus, the ridge structure 11 is formed.

Subsequently, an insulation layer 6 made of SiO₂ and having a thickness of 200 nm is formed above the upper clad layer 5 and on the side faces of the contact layer 8 that are exposed due to etching. Such an insulation layer may be formed using for example the CVD method.

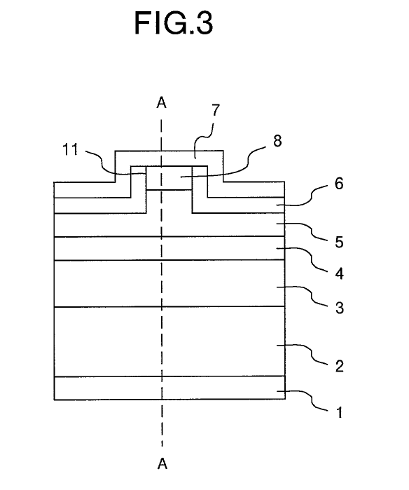

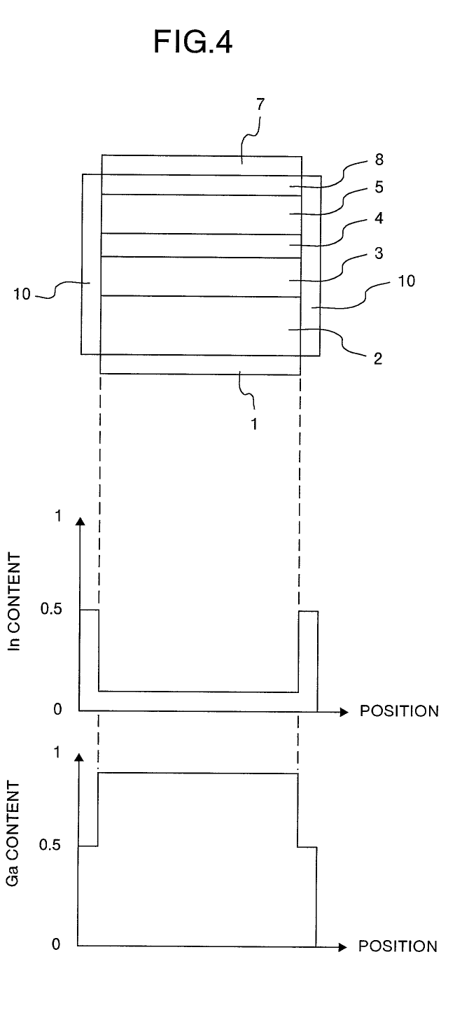

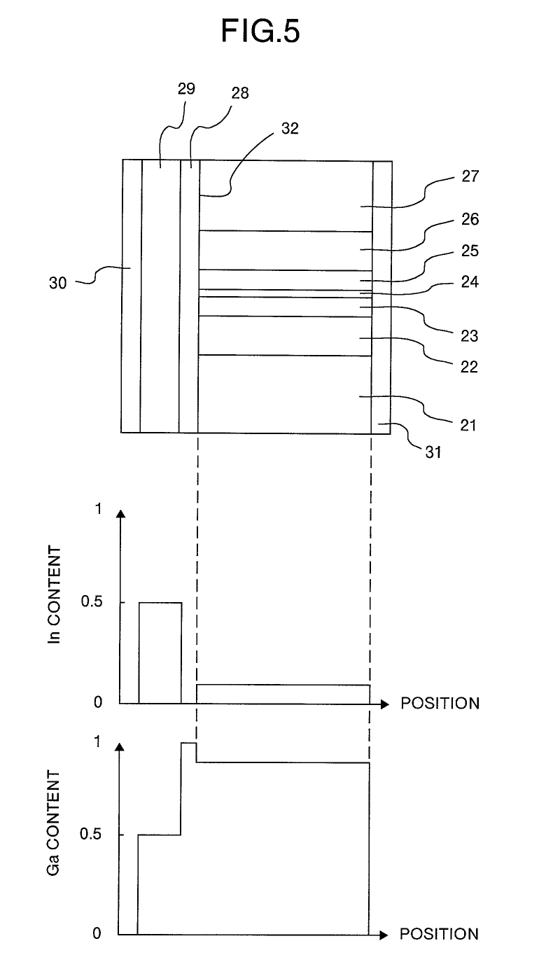

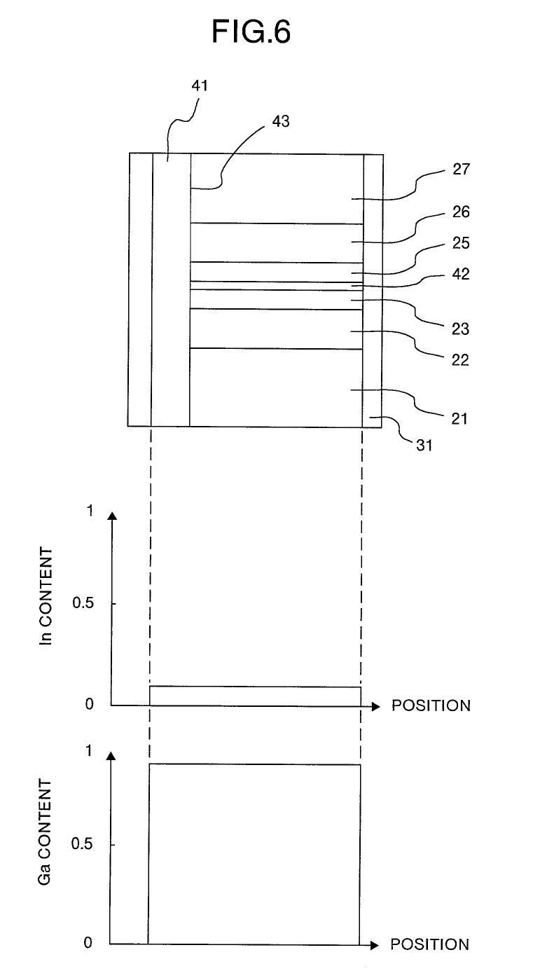

Thereafter, as shown in FIG. 3, the substrate 2 is ground to remove a portion having a thickness of approximately 100 to 200 μm. Subsequently, the electrode 1 made of AuGeNi/Au is formed above the substrate 2, and the electrode 7 made of Ti/Pt/Au is formed above the contact layer 8 and insulation layer 6. The electrode 1 functions as a negative electrode and the electrode 7 functions as a positive electrode.

Then, an oscillator is formed by cleavage along a plane parallel to the plane of this paper with a spacing of 800 to 1200 μm.

FIG. 4 (upper portion) shows a cross section of the semiconductor device along the line A-A shown in FIG. 3. The optical damage suppressing layer 10 made of InGaP and having a thickness of 100 nm is formed on the surface of the oscillator. Such an optical damage suppressing layer may be formed using for example the MOCVD method.

The InGaP layer, which has forbidden band a wider than the forbidden band of the well layer. Japanese Patent Application Laid-Open No. 52-74292 teaches that, the InGaP layer suppresses light absorption at the light emitting end facet and therefore reduces the optical damage. Moreover, the growth temperature of InGaP is advantageously equal to or lower than 600 degree centigrade. Therefore, when forming InGaP layer, a strain quantum well layer that is formed earlier is not disordered. In addition, since InGaP does not contain Al, oxidization tendencies of constituent elements of semiconductor are less. Therefore, the tendency for recombination without light emission is less, resulting into further suppression of optical damage.

However, the demands for the semiconductor laser devices to have still higher output or longer service life is increasing. In this context, the problem of performance deterioration due to an occurrence of crystalline defects in vicinity of an end facet, which is considered due to heat generation at the end facet, is becoming more and more conspicuous.

Conventionally, the well layer i.e. the active layer 4 is made of In_{0.1}Ga_{0.9}As, and the optical damage suppressing layer 10 necessary for a lattice matching with GaAs is made of In_{0.47}Ga_{0.53}P. FIG. 4 (lower portion) shows distributions of In and Ga contents between from the optical damage suppressing layer 10 to the well layer. At an interfacial surface between the well layer and the optical damage suppressing layer 10, the difference between In and Ga contents is as large as 0.37. Further, there was an interfacial potential difference due to re-growth on the interfacial surface between the well layer and the optical damage suppressing layer 10, with light absorption by the interfacial potential difference accompanying occurrences of heat generation. The heat generation was at a significantly high temperature below a crystalline melting point.

Because of such a great difference in the content of the two layers, and heat generation at the interfacial surface, Ga and In exhibit a relative diffusion from higher concentration to lower concentration. The In_{0.1}Ga_{0.9}As of well layer is inherently compression-strained by a 10% addition of In. By the relative diffusion, the well layer has increased In and decreased Ga, with an increase in strain amount of the well layer. A strain amount exceeding a critical value causes a lattice strain relief, resulting in a crystalline defect such as a dislocation, inducing deterioration of laser performance.

On the other hand, in the case of much In diffusion from the optical damage suppressing layer 10 to the well layer with little Ga diffusion from the well layer, the well layer has increased III-family elements, having a broken stoichiometry to V-family elements, with occurrences of point defects such as a void lattice defect or dislocation, still inducing deterioration of laser performance.

Upper part of FIG. 5 shows a lamination structure of the semiconductor laser device according to the first embodiment of the present invention. In this semiconductor laser device, the substrate 21 is made of n-type GaAs. Following layers are stacked sequentially above this substrate 21. That is, the lower clad layer 22 made of n-type AlGaAs and having a thickness of 2 μm, the barrier layer 23 made of GaAs and having a thickness of 20 nm, the compression strain quantum well layer 24 made of In_{0.1}Ga_{0.9}As and having a thickness of 7 nm, the barrier layer 25 made of GaAs and having a thickness of 20 nm, the upper clad layer 26 made of p-type AlGaAs and having a thickness of 2 μm, and the contact layer 27 made of GaAs and having a thickness of 0.5 μm. These layers may be formed using for example the MOCVD method.

Subsequently, in the same manner as the conventional example, the ridge structure, positive and negative electrodes are formed. Then, after cleavage of an entirety, the diffusion preventing layer 28 made of GaP and having a thickness of 2 nm is formed on a light emitting side of the cleavage surface, and outside thereof. Then, the optical damage suppressing layer 29 made of In_{0.47}Ga_{0.53}P and having a thickness of 100 nm is formed. Then, the low reflection film 30 having a reflectivity of 3% is formed on one surface, and the high reflection film 31 having a reflectivity of 98% is formed on the other surface of the cleavage. These layers may be formed using for example the MOCVD method. Thus, the semiconductor laser device of the present invention is obtained.

The lower part of FIG. 5 shows distributions of In and Ga content. The difference between the In content on the boundary 32 between the well layer 24 and the diffusion preventing layer 28 is 0.1.

Threshold current was measured, and it was found that the oscillation wavelength band is 0.98 μm. Just after fabrication, the threshold current was 35±5 mA, and even after an acceleration test with a current of 350 mA conducted to perform laser oscillation over 96 hours, the threshold current was 40±5 mA. No optical damage was observed. In addition, the service life was satisfactorily long.

The diffusion preventing layer 28 has preferably a composition within the range of In_{0-0.2}Ga_{0.8-1}P. For example, the diffusion preventing layer 28 has a composition GaP or In_{0.1}Ga_{0.9}P. The well layer 24 has preferably a composition within the range of In_{0.05-0.2}Ga_{0.8-0.95}As. For example, the well layer 24 has a composition In_{0.1}Ga_{0.9}As.

If the well layer 24 has composition In_{0.1}Ga_{0.9}As, then the diffusion suppressing layer 28 should preferably have a composition In_{0-0.2}Ga_{0.8-1.0}P and a thickness between 2 and 10 nm. With these compositions, the difference in In and Ga content at the boundary between the well layer 24 and the diffusion suppressing layer 28 becomes small. As a result, diffusion is reduced. The reason why the thickness of the diffusion suppressing layer 28 should be between 2 and 10 nm resides in that the In_{0-0.2}Ga_{0.8-1.0}P to be different in lattice constant from GaAs has an increased difficulty in mono-crystallization of an In_{0-0.2}Ga_{0.8-1.0}P film to be formed with an increased film thickness. For example, if the thickness is greater than 10 nm, then crystalline defects occur due to deviations of lattice constant and it becomes more difficult to obtain a mono-crystalline film of good quality.

It has been mentioned above that the In content of the diffusion suppressing layer 28 should preferably be equal to less than 0.2. If the In content is greater than 0.2, the difference in In and Ga content at the boundary between the well layer 24 and the diffusion suppressing layer 28 becomes large. As a result, amount of relative diffusion of In and Ga during laser oscillation becomes significant, and this induces a bad influence on the well layer 24.

The upper portion of FIG. 6 shows a lamination structure of a semiconductor laser device according to a second embodiment of the invention. In this semiconductor laser device, the composition of the well layer 42 is In_{0.1}Ga_{0.9}As, and that of the optical damage suppressing layer 41 is In_{0.1}Ga_{0.9}As_{0.8}P_{0.2}. The reference number 43 indicates the boundary between the well layer 42 and the optical damage suppressing layer 41. The diffusion suppressing layer mentioned in the first embodiment is not provided in this semiconductor laser device. The other layers are same as those in the first embodiment. The lower portion of FIG. 6 shows distributions of In and Ga content in this semiconductor laser device. The In content on the two sides of the boundary 43, i.e. the well layer 42 and the optical damage suppressing layer 41, is the same.

Threshold current measurement of this semiconductor laser device showed that the oscillation wavelength band was 0.98 μm. Just after the fabrication, the threshold current was 35±5 mA, and even after an acceleration test with a current of 350 mA conducted to perform laser oscillation over 96 hours, the threshold current was 40±5 mA. No optical damage was observed. In addition, the service life was satisfactorily long.

Although specific example have been given above, the well layer 41 should preferably have a composition in the range of In_{0.05-0.2}Ga_{0.5-0.95}As, and the optical damage suppressing layer 41 should preferably have a composition in the range of In_{0.08-0.12}Ga_{0.88-0.92}As_{0.76-0.84}P_{0.16-0.24}. As a result, the difference in content of In and Ga at the boundary between these two layers will be small, and hence there will be almost no relative diffusion. In addition, since the lattice constant of In_{0.08-0.12}Ga_{0.88-0.92}As_{0.76-0.84}P_{0.16-0.24} is substantially identical to that of GaAs, crystalline defects due to deviations of lattice constant will not occur. The thickness of the optical damage suppressing layer 41 should preferably be 100 nm.

Although in the first embodiment description was of a strain quantum well semiconductor laser, the present invention is applicable to a general quantum well semiconductor laser.

As described, according to the present invention, a semiconductor laser device having optical damage and satisfactorily long service life is obtained. In other words, the output of the semiconductor laser device can be increased.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device, as at least one quantum well semiconductor laser device, comprising:
a semiconductor substrate made of GaAs;
a lower clad layer on one side of said substrate;
an active layer as at least one well layer made of InGaAs above said lower clad layer;
an upper clad layer above said well layer;
a diffusion preventing layer on at least one surface of said substrate, lower clad layer, well layer, and upper clad layer, wherein said diffusion preventing layer having a forbidden band wider than that of said well layer; and
an optical damage suppressing layer above said diffusion preventing layer, wherein said optical damage suppressing layer having a forbidden band wider than the that of said well layer, and having lattices matching with GaAs.

2. The semiconductor laser device according to claim 1, wherein composition of said diffusion preventing layer is in the range In_{0-0.2}Ga_{0.8-1}P.

3. The semiconductor laser device according to claim 1, wherein thickness of said diffusion preventing layer is between 2 and 10 nm.

4. The semiconductor laser device according to claim 1, further comprising:
a layer having low reflectivity above said optical damage suppressing layer; and
a layer having high reflectivity on a side on which said optical damage suppressing layer is not provided.

5. The semiconductor laser device according to claim 1, further comprising:
a negative electrode layer on the other side of said substrate; and
a positive electrode layer above said upper clad layer.

6. A semiconductor laser device, as at least one quantum well semiconductor laser device, comprising:
a semiconductor substrate made of GaAs;
a lower clad layer on one side of said substrate;
an active layer as at least one well layer made of InGaAs above said lower clad layer;
an upper clad layer above said well layer; and
an optical damage suppressing layer on at least one surface of said substrate, lower clad layer, well layer, and upper clad layer, wherein said optical damage suppressing layer having a forbidden band wider than that of said well layer, and having a composition in the range of In_{0.08-0.12}Ga_{0.88-0.92}As_{0.76-0.84}P_{0.16-0.24}.

7. The semiconductor laser device according to claim 6, further comprising:
a layer having low reflectivity above said optical damage suppressing layer; and
a layer having high reflectivity on a side on which said optical damage suppressing layer is not provided.

8. The semiconductor laser device according to claim 6, further comprising:
a negative electrode layer on the other side of said substrate; and
a positive electrode layer above said upper clad layer.
